(19) United States
(12) Patent Application Publication
(10) Pub. No.: US 2009/0179242 A1
(43) Pub. Date: Jul. 16, 2009

(54) IMAGE SENSOR AND METHOD FOR MANUFACTURING THE SAME

(76) Inventor: Joon Hwang, Cheongju-si (KR)

Correspondence Address: SHERR & VAUGHN, PLLC, 620 HERNDON PARKWAY, SUITE 200, HERNDON, VA, 20170, US

(21) Appl. No.: 12/344,546

(22) Filed: Dec. 28, 2008

(30) Foreign Application Priority Data
Dec. 28, 2007 (KR) 10-2007-0139745
Jun. 30, 2008 (KR) 10-2008-0062701

(51) Int. Cl. H01L 31/112; H01L 21/70

(52) U.S. Cl. 257/292; 438/98; 257/E31.073; 257/E21.532

(57) ABSTRACT

Embodiments relate to an image sensor. According to embodiments, an image sensor may include a metal interconnection and readout circuitry over a first substrate, a metal layer over the metal interconnection, and an image sensing device electrically connected to the metal layer. According to embodiments, an electric field may not be generated on and/or over an Si surface. This may contribute to a reduction in a dark current of a 3D integrated CMOS image sensor.

The present application claims priority under 35 U.S.C. 119 to Korean Patent Application No. 10-2007-0139745 (filed on Dec. 28, 2007), and to Korean Patent Application No. 10-2008-0062701 (filed on Jun. 30, 2008), which are hereby incorporated by reference in their entireties.

### BACKGROUND

An image sensor may be a semiconductor device that may convert an optical image into an electrical signal. An image sensor may be classified into categories, such as a charge coupled device (CCD) image sensor and a complementary metal oxide silicon (CMOS) image sensor (CIS).

During a fabrication process of an image sensor, a photodiode may be formed in a substrate using ion implantation. A size of a photodiode may be reduced to increase a number of pixels without increasing a chip size. This may reduce an area of a light receiving portion. Image quality may thereby be reduced.

Since a stack height may not reduce as much as a reduction in an area of a light receiving portion, a number of photons incident to a light receiving portion may also be reduced due to diffraction of light called Airy disk.

To address this limitation, a photodiode may be formed using amorphous silicon (Si). In addition, readout circuitry may be formed in a silicon (Si) substrate using a method such as wafer-to-wafer bonding, and a photodiode may be formed on and/or over readout circuitry (referred to as a three-dimensional (3D) image sensor). A photodiode may be connected with readout circuitry through a metal interconnection.

A metal interconnection may be formed on and/or over a readout circuitry and a wafer-to-wafer bonding may be performed and may contact a metal interconnection to a photodiode. It may be difficult to achieve a correct contact between a metal interconnection and a photodiode and it may also be difficult to achieve an ohmic contact between the metal interconnection and the photodiode.

Since both a source and a drain at both sides of a transfer transistor may be heavily doped with N-type impurities, a charge sharing phenomenon may occur. When a charge sharing phenomenon occurs, a sensitivity of an output image may be reduced and an image error may be generated. In addition, because a photo charge may not readily move between a photodiode and readout circuitry, a dark current may be generated and/or saturation and sensitivity may be reduced.

### SUMMARY

Embodiments relate to an image sensor and a method of manufacturing the same. Embodiments relate to an image sensor and a manufacturing method thereof that may enhance a physical bonding force between a photodiode and a metal interconnection. Embodiments relate to an image sensor and a method of manufacturing the same which may increase a fill factor and obtain an ohmic contact.

Embodiments relate to an image sensor and a manufacturing method thereof that may prevent charge sharing while increasing a fill factor. Embodiments relate to an image sensor and a manufacturing method thereof that may minimize a dark current source and may prevent reduction in saturation and sensitivity by providing a relatively swift movement path for a photo charge between a photodiode and readout circuitry.

According to embodiments, an image sensor may include at least one of the following. A metal interconnection and readout circuitry over a first substrate. A metal layer over the metal interconnection. An image sensing device electrically connected to the metal layer.

According to embodiments, a method for manufacturing an image sensor may include at least one of the following. Forming a metal interconnection and a readout circuitry over a first substrate. Forming a metal layer over the metal interconnection. Forming an image sensing device. Bonding the metal layer and the image sensing device so that the metal layer and the image sensing device are bonded together.

### DRAWINGS

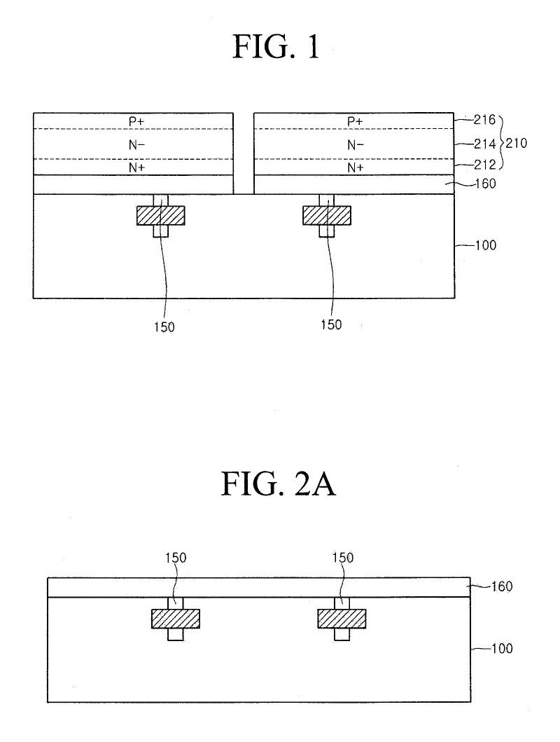

Example FIGS. 1 through 9 illustrate an image sensor and a method for manufacturing an image sensor, according to embodiments.

### DESCRIPTION

An image sensor and a method for manufacturing an image sensor according to embodiments will be described with reference to the accompanying drawings.

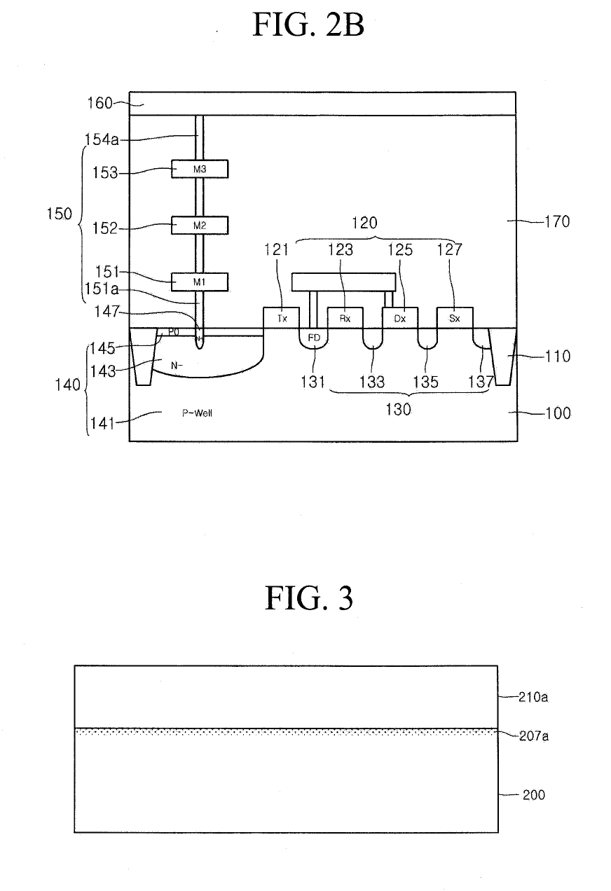

Example FIG. 1 is a sectional view of an image sensor according to embodiments. Referring to example FIG. 1, an image sensor may include metal interconnection 150 and readout circuitry 120 (see FIG. 2B) on and/or over first substrate 100. Metal layer 160 may be provided on and/or over metal interconnection 150. Image sensing device 210, which may include first conduction type conduction layer 214 and second conduction type conduction layer 216, may be electrically connected to metal layer 160.

According to embodiments, image sensing device 210 may be a photodiode, a photogate or any combination thereof. For simplicity in description, it will be referred to a photodiode 210. According to embodiments, a photodiode may be formed in a crystalline semiconductor layer. According to embodiments, a photodiode may not be limited thereto, but may be formed in other layer types, including in an amorphous semiconductor layer.

Example FIG. 2A is a schematic view of first substrate 100, which may include metal interconnection 150 and readout circuitry 120, according to embodiments. Example FIG. 2B is another view of first substrate 100, according to embodiments.

Referring to example FIG. 2B, a method for manufacturing an image sensor according to embodiments may include preparing first substrate 100. Metal interconnection 150 and readout circuitry 120 may be formed on and/or over first substrate 100. According to embodiments, first substrate 100 may be a second conduction type substrate. According to embodiments, first substrate 100 may not be limited to a second conduction type substrate, but could be any conduction type.

According to embodiments, device isolation layer 110 may be formed in second conduction type first substrate 100 and may define an active region. Readout circuitry 120, which may include at least one transistor, may be formed in the active region. According to embodiments, readout circuitry 120 may include transfer transistor (Tx) 121, reset transistor (Rx) 123, drive transistor (Dx) 125, and select transistor (Sx) 127. Floating diffusion region (FD) 131 of ion implantation regions 130, which may include source/drain regions 133, 135, and 137 of respective transistors may be formed.

According to embodiments, forming readout circuitry 120 on and/or over first substrate 100 may include forming electrical junction region 140 in first substrate 100 and forming first conduction type connection region 147 in an upper region of electrical junction region 120. According to embodiments, first conduction type connection region 147 may be electrically connected to metal interconnection 150.

According to embodiments, electrical junction region 140 may be a PN junction, but may not be limited thereto. According to embodiments, electrical junction region 140 may include first conduction type ion implantation layer 143 formed on and/or over second conduction type well 141 and/or a second conduction type epitaxial layer, and may include second conduction type ion implantation layer 145 formed on and/or over first conduction type ion implantation layer 143. According to embodiments, PN junction 140 may be a P0 (145)/N− (143)/P− (141) junction. PN junction 140 may not be limited to such a configuration, however, and may be any junction configuration.

According to embodiments, a device may be designed such that there may be a potential difference between a source and drain on both sides of transfer transistor (Tx) 121. This may allow a photo charge to be fully dumped. Accordingly, a photo charge generated from a photodiode may be fully dumped to a floating diffusion region. This may maximize a sensitivity of an output image.

Electrical junction region 140 may be formed in first substrate 100, and proximally located to readout circuitry 120. Electrical junction region 140 may permit generation of a potential difference between a source and a drain on both sides of transfer transistor (Tx) 121. This may allow a photo charge to be fully dumped.

Hereinafter, a dumping structure of a photo charge will be further described, according to embodiments. Unlike a node of floating diffusion region (FD) 131, which may be an N+ junction, P/N/P junction 140, which may be electrical junction region 140 and to which an applied voltage may not be fully transferred, may be pinched-off at a predetermined voltage. This voltage may be called a pinning voltage, and may depend on doping concentrations of P0 region 145 and N− region 143.

According to embodiments, an electron generated from photodiode 210 may move to PNP junction 140, and may be transferred to a node of floating diffusion region (FD) 131. It may then be converted into a voltage if transfer transistor (Tx) 121 is turned on.

According to embodiments, since a maximum voltage value of P0/N−/P− junction 140 may become a pinning voltage, and a maximum voltage value of a node of floating diffusion region (FD) 131 may become threshold voltage Vth of Vdd-Rx 123, an electron generated from photodiode 210 in an upper portion of a chip may be fully dumped to a node of floating diffusion region (FD) 131. This may be done without charge sharing due to a potential difference between both sides of transfer transistor (Tx) 131.

According to embodiments, a P0/N−/P-well junction, not an N+/P-well junction, may be formed in a silicon substrate such as first substrate 100. Hence, a + voltage may be applied to N− 143 of P0/N−/P-well junction and a ground voltage may be applied to P0 145 and P-well 141 during a 4-Tr active pixel sensor (APS) reset operation. A pinch-off may thus be generated to P0/N−/P-well double junction at a predetermined voltage or more. This may be similar to a bipolar junction transistor (BJT) structure. This may be called a pinning voltage. According to embodiments, a potential difference may be generated between a source and a drain at both sides of transfer transistor (Tx) 121, which may prevent a charge sharing phenomenon during on/off operations of transfer transistor (Tx) 121.

According to embodiments, unlike a case where a photodiode may simply be connected to an N+ junction, limitations such as saturation reduction and sensitivity reduction may be avoided.

According to embodiments, first conduction type connection region 147 may be formed between a photodiode and readout circuitry and may provide a relatively swift movement path of a photo charge. This may minimize a dark current source, and may prevent saturation reduction and sensitivity reduction.

According to embodiments, first conduction type connection region 147 for ohmic contact, for example, N+ region 147, may be formed on and/or over a surface of P0/N−/P− junction 140. N+ region 147 may be formed and may extend through P0 region 145 and contact N− region 143. According to embodiments, to prevent first conduction type connection region 147 from becoming a leakage source, a width of first conduction type connection region 147 may be minimized. Therefore, according to embodiments, a plug implant may be performed after first metal contact 151a may be etched. According to embodiments, a process may not be limited thereto. For example, an ion implantation pattern may be formed and first conduction type connection region 147 may then be formed using the ion implantation pattern as an ion implantation mask.

According to embodiments, by locally and heavily doping only a contact forming portion with N-type impurities, ohmic contact formation may be facilitated while minimizing a dark signal. If an entire transfer transistor source were heavily doped, a dark signal may be increased by a Si surface dangling bond.

According to embodiments, interlayer dielectric 160 may be formed on and/or over first substrate 100. Metal interconnection 150 may be formed and may extend through interlayer dielectric 160 and may be electrically connected to first conduction type connection region 147. According to embodiments, metal interconnection 150 may include first metal contact 151a, first metal 151, second metal 152, third metal 153, and fourth metal contact 154a. According to embodiments, other structures could be used.

According to embodiments, metal layer 160 may be formed on and/or over first substrate 100 and may contact metal interconnection 150. According to embodiments, a bonding force between substrates may be enhanced by interposing metal layer 160 between first substrate 100 and photodiode 210. According to embodiments, metal layer 160 may be an aluminum (Al) layer. According to embodiments, metal layer 160 may be formed of other metals.

According to embodiments, metal layer 160 may be formed of aluminum (Al) and may have a thickness range between approximately 100 Å and about 500 Å. Metal layer may act as a medium between metal interconnection 150 and photodiode 210. This may enhance physical and electrical bonding forces between substrate 200 where photodiode 210 may be formed and substrate 100 where readout circuitry 120 may be formed.

According to embodiments, metal layer 160 may be formed of titanium (Ti). For example, metal layer 160 may be formed of titanium (Ti) in thickness range between approximately 50 Å and 500 Å. Metal layer 160 may be a medium between metal interconnection 150 and photodiode 210. This may enhance physical and electrical bonding forces between substrate 200 where photodiode 210 may be formed and substrate 100 where readout circuitry 120 may be formed.

According to embodiments, an image sensor may enhance physical and electrical bonding forces between photodiode and metal interconnection by providing a metal layer between a photodiode and a metal interconnection and bonding them while employing a vertical type photodiode.

Referring to example FIG. 3, crystalline semiconductor layer 210a may be formed on and/or over second substrate 200. According to embodiments, in an image sensor such as that illustrated in example FIG. 1, photodiode 210 may be formed on and/or over crystalline semiconductor layer. Thus, a fill factor may be enhanced. This may be because an image sensing device may employ a 3D image sensor disposed on and/or over readout circuitry 120, and defects within an image sensing device may be prevented by forming an image sensing device in a crystalline semiconductor layer.

According to embodiments, crystalline semiconductor layer 210a may be epitaxially formed on and/or over second substrate 200. According to embodiments, hydrogen ion implantation layer 207a may be formed by implanting hydrogen ions into a boundary between second substrate 200 and crystalline semiconductor layer 210a. An implantation of hydrogen ions may be performed after ion implantation for forming photodiode 210.

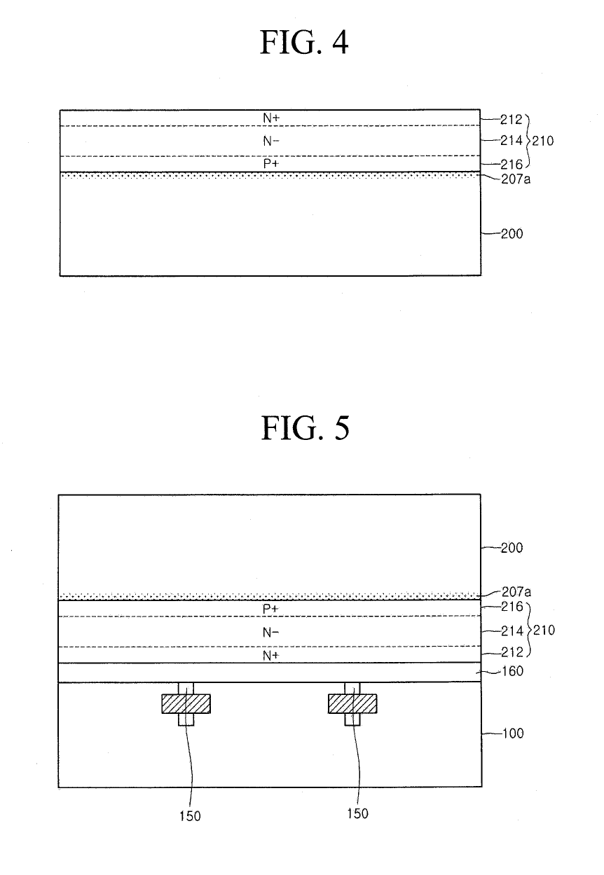

Referring to example FIG. 4, photodiode 210 may be formed by implanting ions into crystalline semiconductor layer 210a. According to embodiments, second conduction type conduction layer 216 may be formed under and/or below crystalline semiconductor layer 210a. High-concentration P-type conduction layer 216 may be formed under and/or below crystalline semiconductor layer 210a by implanting ions into second substrate 200. According to embodiments, ion implantation may be performed in a blanket manner without mask.

According to embodiments, first conduction type conduction layer may be formed on and/or over second conduction type conduction layer 216. For example, low-concentration N-type conduction layer 214 may be formed on and/or over second conduction type conduction layer 216 by implanting ions over second substrate 200 in a blanket manner without mask.

According to embodiments, high-concentration first conduction type conduction layer 212 may be formed on and/or over first conduction type conduction layer 214. For example, high-concentration N+ type conduction layer 212 may be formed on and/or over first conduction type conduction layer by implanting ions into second substrate in a blanket manner without mask. This may contribute to an ohmic contact.

Referring to example FIG. 5, first substrate 100 and second substrate 200 may be bonded together and may contact photodiode 210 with metal layer 160. According to embodiments, before bonding first substrate 100 and second substrate 200, bonding may be performed by increasing a surface energy of a surface to be bonded, for example through activation by plasma. According to embodiments, bonding may be performed by disposing an insulating layer and a metal layer in a bonding boundary. This may enhance a bonding force.

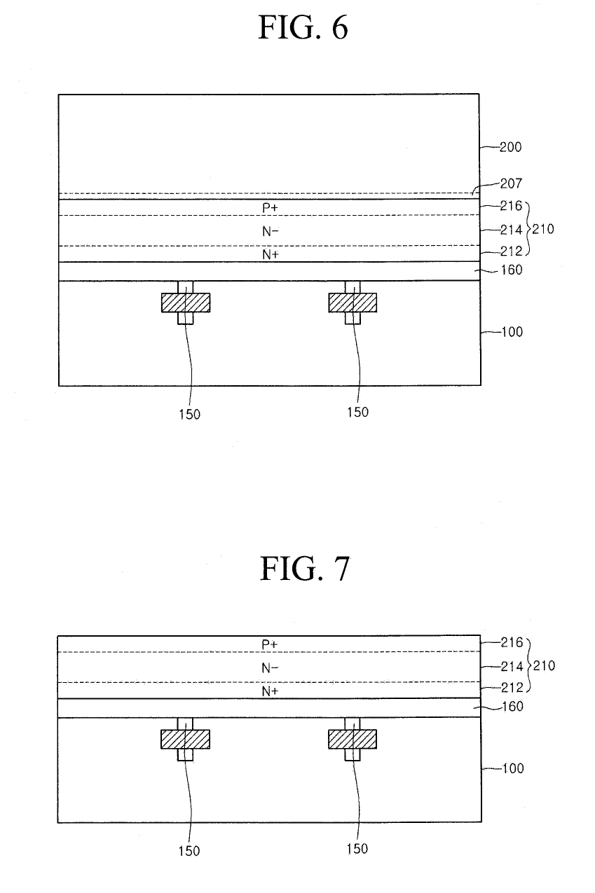

Referring to example FIG. 6, hydrogen ion implantation layer 207a may be changed to a hydrogen gas layer by performing a thermal treatment on and/or over second substrate 200.

Referring to example FIG. 7, a portion of second substrate 200 may then be removed. According to embodiments, photodiode 210 may be left under the hydrogen gas layer and photodiode 210 may be exposed. According to embodiments, removal of second substrate 200 may be performed using a cutting apparatus such as a blade.

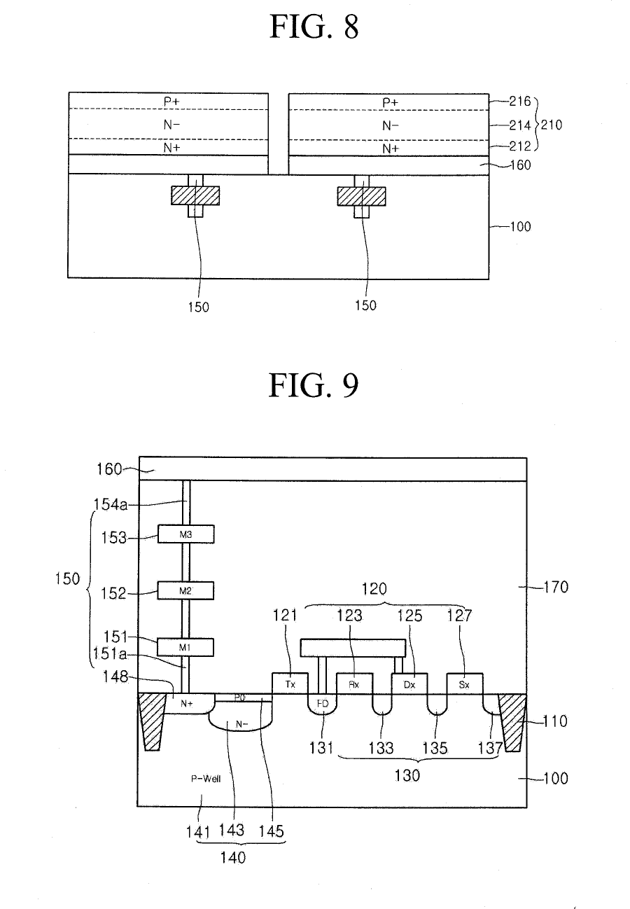

Referring to example FIG. 8, an etching process may be performed and may separate a photodiode for each unit pixel. According to embodiments, an etched portion may be filled with an interpixel dielectric. According to embodiments, processes to form an upper electrode and a color filter may be performed.

Example FIG. 9 is a sectional view of an image sensor according to embodiments. Example FIG. 9 includes a sectional view of first substrate 100 on and/or over which metal interconnection 150 may be formed. According to embodiments, a device illustrated in example FIG. 1 may adopt certain technical characteristics of embodiments illustrated in example FIG. 9.

Unlike embodiments illustrated in example FIG. 9, according to embodiments, first conduction type connection region 148 may be formed to be spaced laterally on one side of electrical junction region 140.

According to embodiments, N+ connection region 148 for ohmic contact may be formed on and/or over P0/N−/P− junction 140. According to embodiments, a process of forming N+ connection region 148 and M1C contact 151a may provide a leakage source. This may be because a device may operate with a reverse bias applied to P0/N−/P− junction 140 and an electric field (EF) may be generated on and/or over an Si surface. A crystal defect that may be generated during a contact forming process inside an electric field may serve as a leakage source.

According to embodiments, if N+ connection region 148 is formed on and/or over a surface of P0/N−/P− junction 140, an electric field may be generated due to N+/P0 junction 148/145. This electric field may also serve as a leakage source.

According to embodiments, a layout may be provided in which first contact plug 151a may be formed in an active region not doped with a P0 layer but including N+ connection region 148 and may be connected to N− junction 143.

According to embodiments, an electric field may not be generated on and/or over an Si surface. This may contribute to reduction in a dark current of a 3D integrated CIS.

Although embodiments have been described with respect to a complementary metal oxide semiconductor (CMOS) image sensor, embodiments are not limited thereto. According to embodiments, any image sensor requiring a photodiode may be used.

It will be obvious and apparent to those skilled in the art that various modifications and variations can be made in the embodiments disclosed. Thus, it is intended that the disclosed embodiments cover the obvious and apparent modifications and variations, provided that they are within the scope of the appended claims and their equivalents.

What is claimed is:

1. A device, comprising:
a metal interconnection and a readout circuit over a first substrate;
a metal layer over the metal interconnection; and
an image sensing device electrically connected to the metal layer.

2. The device of claim 1, wherein the metal layer comprises aluminum (Al).

3. The device of claim 2, wherein the metal layer has a thickness ranging from approximately 100 Å to 500 Å.

4. The device of claim 1, wherein the metal layer comprises titanium (Ti).

5. The device of claim 4, wherein the metal layer has a thickness ranging from approximately 50 Å to 500 Å.

6. The device of claim 1, wherein the readout circuit comprises an electrical junction region over the first substrate.

7. The device of claim 6, wherein the electrical junction region comprises:
a first conduction type ion implantation region in the first substrate; and
a second conduction type ion implantation region over the first conduction type ion implantation region.

8. The device of claim 7, comprising a first conduction type connection region electrically connected to the metal interconnection over the electrical junction region.

9. The device of claim 7, comprising a first conduction type connection region spaced away from the electrical junction region and electrically connected to the metal interconnection.

10. The device of claim 1, wherein the readout circuit comprises a transistor, configured such that a potential difference exists between a source and a drain at both sides of the transistor.

11. The device of claim 10, wherein the transistor comprises a transfer transistor, and wherein an ion implantation concentration of the source of the transistor is lower than an ion implantation concentration of a floating diffusion region.

12. A method, comprising:
forming a metal interconnection and a readout circuit over a first substrate;
forming a metal layer over the metal interconnection;
forming an image sensing device over the metal layer; and
bonding the metal layer and the image sensing device together.

13. The method of claim 12, wherein the metal layer comprises aluminum (Al).

14. The method of claim 13, comprising forming the metal layer to have a thickness in a range of approximately 100 Å to 500 Å.

15. The method of claim 12, wherein the metal layer comprises titanium (Ti).

16. The method of claim 15, comprising forming the metal layer to have a thickness in a range of approximately 50 Å to 500 Å.

17. The method of claim 12, wherein forming the readout circuit comprises forming an electrical junction region over the first substrate, and wherein forming the electrical junction region comprises:
forming a first conduction type ion implantation region in the first substrate; and
forming a second conduction type ion implantation region over the first conduction type ion implantation region.

18. The method of claim 17, comprising forming a first conduction type connection region connected to the metal interconnection over the electrical junction region.

19. The method of claim 18, comprising forming the first conduction type connection region after forming a contact to couple with the metal interconnection.

20. The method of claim 18, comprising forming a first conduction type connection region spaced apart from the electrical junction region and electrically connected to the metal interconnection.
